(19) United States
(12) Patent Application Publication
(10) Pub. No.: US 2004/0133831 A1
(43) Pub. Date: Jul. 8, 2004

(54) Semiconductor device and method and apparatus for testing such a device

(76) Inventors: Emrys Williams, Milton Ketnes (GB); Kenneth Alan House, Arlington, MA (US); Joseph Raymond Siegel, Shrewsbury, MA (US)

Correspondence Address: B. Noel Kivlin, Meyertons, Hood, Kivlin,, Kowert & Goetzel, P.C., P.O. Box 398, Austin, TX, 78767, US

(21) Appl. No.: 10/337,573

(22) Filed: Jan. 7, 2003

(51) Int. Cl. G01R 31/28

(52) U.S. Cl. 714/726

(57) ABSTRACT

A semiconductor device can be subjected to scan testing by using an input scan test vector. This input scan test vector is processed by the device to produce an output scan test vector, which can be used for diagnostic purposes with respect to the device. There are certain locations in this output scan test vector that may be indeterminate in value, even for a correctly functioning device. In other words, it is not possible to predict beforehand what values the output scan test vector will have at these locations. Therefore, an output mask vector is provided that identifies those locations in the output scan test vector that are indeterminate. This mask vector is then combined with the output scan test vector using a logical operation to produce a determinate masked output scan test vector. For example, if all the indeterminate locations are flagged by a 1 in the mask vector, then using OR for the logical operation will ensure that the output for these locations is always a 1. Having a fully determinate output vector allows a signature to be calculated for this vector, and this signature will have a predetermined value for a correctly functioning device.

### RELATED APPLICATION

The present application is related to the U.S. patent application Ser. No. ______ (assignee reference number P6587), filed concurrently herewith, and sharing the same title, inventors, and assignee as the present application, the teachings of which are incorporated by reference herein.

### FIELD OF THE INVENTION

The present invention relates to semiconductor devices, and in particular to the testing of such devices.

### BACKGROUND OF THE INVENTION

Modern computer systems typically involve many components interacting with one another in a highly complex fashion. For example, a server installation may have multiple processors, configured either within individual (uniprocessor) machines, or combined into one or more multiprocessor machines. Such computer systems operate in conjunction with associated memory and disk drives for storage, video terminals and keyboards for input/output, plus interface facilities for data communications over one or more networks. The skilled person will appreciate that many additional components may also be present.

The pervasive use of such computer systems in modern day society places stringent requirements on their reliability. For example, it is especially important that the storage, manipulation and transmission of commercially significant information can all be performed correctly, without the introduction of errors. It is therefore of great importance that computer systems are correctly designed and built, and also that they continue to perform properly during their operational lifetime.

This in turn generates the need to be able to reliably test computer systems, especially during initial system design and construction. In addition it is also highly desirable to be able to test machines or components of machines in situ at customer premises, in a production environment. For example, the situation may arise where a processing error is suspected or detected in a customer system, but the source of the error is obscure. Since a typical server installation may be formed from multiple hardware and software components (each of which may potentially be supplied by a different vendor), tracing the error to its original source can be a difficult task. In such circumstances, the ability to show that at least certain components are properly functional can help to isolate the location of the fault. Indeed, even in situations where there is no particular evidence that a fault is present, it can still be desirable to be able to positively demonstrate at a customer location that a particular component (such as a newly installed device) is working properly.

One standard way of checking that hardware components are operating properly is by performing a functional test. In order to achieve this, a particular hardware unit is given some input data to process. It is then confirmed that the output from the unit represents the expected result for the given input data.

Unfortunately, the complexity of modern systems means that such functional testing can suffer from certain limitations. Thus the employment of multiprocessing cores within a single CPU, along with techniques such as register renaming, asynchronous IO, and out-of-order execution, make it difficult to determine in advance the exact processing sequence within a given hardware device. For example, microscopic timing variations from one program run to another may impact the precise execution strategy, such as which operations are performed in which particular processing core, and using which particular registers. (Of course, this will normally be transparent to programs running on the system).

As a result, it is difficult to be completely confident that all components in the system have been properly exercised when performing a functional test. For example, imagine that a particular register is potentially faulty, but that only some executions of a functional test program will actually utilise this register. In this situation, it is difficult to be certain that a positive result for a functional test is due to the fact that the register is indeed properly operational, rather than the register in question simply not being used for that particular execution.

One known alternative (or complement) to functional testing is scan testing, which can help address the above problem. Scan testing is typically applied to semiconductor devices, and is described, for example, in “Fault Diagnosis of Digital Circuits” by V Yarmolik, Wiley, 1990 (ISBN 0 471 92680 9).

FIG. 1 illustrates in simplified schematic form one stage of a generalised semiconductor processing device, in which combinational logic 15 is interposed between flip-flop 12 and flip-flop 14 (the flip-flops may also be replaced by registers and such like). At each clock signal (CLK), the contents of flip-flop 12 are output to combinational logic 15, and the contents of flip-flop 14 are output to the next stage (indicated by arrow C in FIG. 1). Flip-flop 12 then receives new contents from a preceding stage in the device (indicated by arrow A in FIG. 1), while the output of combinational logic 15 is loaded into flip-flop 14.

A complicated semiconductor device can then be regarded as formed from a large number of stages such as shown in FIG. 1. (Note that each stage comprises combinational logic plus a single flip-flop, so that, strictly speaking, FIG. 1 depicts one and a half stages, with flip-flop 12 and logic 15 forming a first stage, and flip-flop 14 then representing the input side of the next stage).

The various stages in a semiconductor device can be connected together in a highly complex manner (rather than just simply having a linear chain of one stage after another). For example, as shown in FIG. 1, combinational logic 15 may receive input for processing from more than one preceding stage (indicated schematically in FIG. 1 by arrows A and B). Similarly, the output from one stage may be split and directed to multiple other stages, including feedback loops and so on.

FIG. 2 illustrates a modification to the circuit of FIG. 1 in order to support scan testing. The components from FIG. 1 are supplemented in FIG. 2 by the addition of two multiplexers, MX 18 and MX 20, which are located in front of flip-flop 12 and flip-flop 14 respectively. Each multiplexer has two inputs, with the selection of the output from the multiplexers being controlled by a SCAN signal.

Considering the operation of multiplexer 20, when the SCAN signal is not set (i.e., has a value 0), then multiplexer 20 outputs to flip-flop 14 the signal that it receives from combinational logic 15. Thus in this mode, the presence of multiplexer 20 is, in effect, transparent, and the circuit operates in the same manner as described in relation to FIG. 1. However, when the SCAN signal is asserted (i.e., has a value 1), multiplexer 20 now outputs its second input, which is received from bypass line 25, which in turn is linked to the output of flip-flop 12. The consequence of this is that in scan mode (i.e., with the SCAN signal asserted), for each clock signal the contents of flip-flop 12 are simply shifted to flip-flop 14, as if combinational logic 15 were not present.

Multiplexer 18 operates in analogous fashion to multiplexer 20. Thus in normal mode, without the SCAN signal being asserted, its output corresponds to input A. However, in scan mode, its output now corresponds to input A′, which represents a direct connection to the output of a preceding flip-flop (not shown in FIG. 2), similar to bypass line 25.

To support full scan testing of a semiconductor device, the configuration of FIG. 2 is repeated for all relevant stages in the device. Thus a sequence of flip-flops is defined, with each flip-flop being preceded by a multiplexer. The zero input to each of the multiplexers represents the normal operational input to the flip-flop, while the one input is connected by a bypass line to the preceding flip-flop in the sequence. In scan mode therefore, when the one input to the multiplexer is selected, the sequence of flip-flops from all the different stages operates in effect as a long shift register, in which the contents of a flip-flop progress to the next flip-flop in the sequence at every clock signal.

The support of scan mode provides a mechanism both to read data into the flip-flops of a semiconductor device, and also to read data out of the flip-flops. One use of this is to verify that the device properly processes a predefined input sequence. The granularity of this testing can be as fine as one processing operation (i.e. one clock cycle).

This is illustrated schematically in FIGS. 3A-D, which each depict a sequence of flip-flops F1, F2, F3, and F4 respectively interlinked by combinational logic CL1, CL2, and CL3. Arrows A and C represent an external input and output facility respectively for the scan sequence, for example through appropriate pins on the semiconductor device. In FIG. 3A there is a binary data sequence of 110 to be input to the device (this is referred to as the input scan vector). Keeping the system in scan mode, after the first clock cycle, the 0 value is read into F1. After the second clock cycle, the 0 value is shifted into F2, while the 1 is read into F1. Next, after the third clock cycle, the 0 and 1 are shifted from F2 to F3 and from F1 to F2 respectively, while the last 1 of the input is read into F1. This leads to the position shown in FIG. 3B, in which the device has now been primed in effect to a predetermined starting state, as specified by the input scan vector.

We now suspend scan mode for a single processing cycle, which leads to the situation in FIG. 3C. This processing operation results in new data values being stored in F2, F3, and F4. The values stored are dependent on the input scan vector and the particular format of logic CL1, CL2, and CL3, and in FIG. 3C are assumed (for illustration) to be 1, 0, and 1. Re-asserting scan mode then allows the data values generated as a result of this processing to be read out in three clock cycles, as per FIG. 3D, to form an output scan vector.

It will be appreciated that analysis of the output scan vector for a given input scan vector provides a very powerful diagnostic tool for confirming that the various parts of a semiconductor device are properly operational. Consequently, scan testing is frequently employed in semiconductor fabrication plants, typically as part of the assembly line process.

Note that although in both FIG. 2 and FIGS. 3A-D, the sequence in which the flip-flops are connected up for scan testing corresponds to the normal operational flow of data through the flip-flops, this will not generally be the case. Indeed, this would actually be impossible for most devices, since as mentioned above, the normal data flow typically includes branches and such like, and so cannot be represented by a single chain or sequence of flip-flops.

As an example of this, although FIG. 2 shows bypass line 25 linking flip-flop 12 to flip-flop 14 in the same direction as data flow for standard processing, it would also be possible for the scan sequence to go in the opposite direction, i.e. a bypass line to go from the output of flip-flop 14 into multiplexer 18. In this case the bypass output of flip-flop 12 would go to some other multiplexer (not multiplexer 20), and likewise the bypass input of multiplexer 20 would come from some other flip-flop (not flip-flop 12).

In devices containing a large number of flip-flops, the bypass lines linking up the flip-flops into a single sequence for scan mode sometimes have to follow rather lengthy and indirect paths. This is primarily because priority in terms of layout is given to optimising the standard data flow of the device (i.e. through the combinational logic). Consequently, the clock rate for scan mode is usually significantly less than the normal clock rate of the device, to avoid any possible problems with signal timing on the relatively long bypass connections. Typically this reduced clock rate is achieved by providing a reduced (scan) rate clock signal to the clock line (CLK in FIG. 2).

Returning to FIG. 3C, which illustrates the outcome of performing a single processing step on the input scan vector loaded into FIG. 3B, in most devices it is not possible to fully predict this outcome, even when the device is operating correctly. For example, it may be that in FIG. 3C the value stored into flip-flop F3 as a result of the processing can be 0 or 1, leading in turn to an overall output scan vector of 101 or 111, respectively. Both of these two output scan vectors are then compatible with the device functioning properly.

One reason for this lack of complete predictability is that some of the results may be dependent on the state of one or more components (such as an SRAM) that are not included in the scan chain, and which therefore cannot be (re)set to a predetermined state by the input scan vector. Another reason is that certain components may have an indeterminate output for a particular input combination, or until some relatively long time period has expired. In the latter case, the system can be designed to avoid reliance upon indeterminate outputs during normal operation. However, this is not necessarily possible in scan mode, where the flip-flops are being operated, in effect, as a single long shift register.

In a typical modern semiconductor device it is not unusual for some 5-10% of the locations in an output scan vector to have an unpredictable or indeterminate value. (Note that it is possible to identify which particular locations are indeterminate from a design knowledge of the device). Given that it is not uncommon for modem devices to have scan sequences of say 20,000 flip-flops, with input and output scan vectors sized accordingly, the number of indeterminate locations in the output scan vector can therefore be rather large. This makes analysing the results of the scan test more awkward. It is also particularly troublesome for scan tests conducted in the field (i.e. in a production environment rather than at a manufacturer's location), where it is highly desirable for the scan test procedure to be as highly automated and straightforward as possible.

### SUMMARY OF THE INVENTION

Thus there is provided in accordance with one embodiment of the invention a method for scan testing a semiconductor device. The method comprises providing an input scan test vector, and processing the input scan test vector through the device to produce an output scan test vector. This output scan test vector comprises a sequence of locations, each of which has a value. One or more of these locations has a value that is, a priori, indeterminate, even for a correctly functioning device. The method further comprises providing an output mask vector that identifies those locations in the output scan test vector that are, a priori, indeterminate in value. The output scan test vector is then combined with the output mask vector using a logical operation in order to produce a determinate masked output scan test vector.

It will be appreciated that having an output that is completely determinate facilitates automatic testing, particularly of devices in the field. This is because it is straightforward to determine whether or not a device is operating properly by comparing the masked output scan test vector against some predetermined fixed template, without having to worry about how to identify and handle any potentially indeterminate values. This approach can be used for semiconductor devices included in a very wide range of electronic equipment, such as computer systems, aeroplanes, telecommunications networks, and so on. Such testing may be performed by service engineers, or by the device or system itself. In the latter case the system may, for example, be triggered to perform a scan test of a device incorporated within the system at start-up, or in response to some error report. Typically this can be achieved by a control facility within the system sending a command to a device to perform the scan test, with the device then reporting back to the control facility on the result of the test.

In one embodiment, a signature of the masked output scan test vector is produced. This can be conveniently achieved by using a hashing function, or by passing the vector through a linear feedback shift register. This signature provides a highly compact representation of the results of the scan test, which can then be easily and quickly compared against a predetermined value to determine whether or not the device is functioning correctly. The use of a signature in this manner exploits the fully determinate nature of the masked output scan test vector, in that if any indeterminate values were present, these would preclude any useful prediction of the correct signature value. According to one particular implementation, the comparison of the signature is performed within the test device itself, with any mismatch then being flagged back to an appropriate control facility, for example, by sending an interrupt.

In one embodiment, the output mask vector is provided in compressed form, thereby minimising storage and transmission requirements for this vector. As a consequence, the method further comprises the step of decompressing the output mask vector prior to combining it with the output scan test vector. Note that the output mask vector will typically be highly amenable to compression (i.e. a good compression ratio can be achieved), because often only a relatively small fraction of the output scan test vector will need to be masked.

The output mask vector is typically provided as a binary file containing a series of values, each corresponding to a counterpart location in the output scan test vector. In one embodiment, the values of the output mask vector corresponding to indeterminate locations in the output scan test vector are set to 1, and the remaining values in the output mask vector are set to 0. In this case, the basic logical operation used to combine the output scan test vector and the mask vector is an OR function. It is also possible to use a mask vector having the opposite polarity, in which case an AND function would be used for the logical operation instead. Alternatively, rather than using the output mask vector in this manner to set any (a priori) indeterminate values to a fixed value, the output mask vector could instead be used to excise the indeterminate values from the output scan vector.

In accordance with another embodiment of the invention there is provided a method for scan testing a device, comprising the steps of processing an input scan test vector through the device to produce an output scan test vector, and then combining the output scan test vector with an output mask vector in order to produce a determinate masked output scan test vector.

In accordance with yet another embodiment of the invention, there is provided apparatus for scan testing a device. This apparatus comprises means for providing an input scan test vector to be processed through the device in order to produce an output scan test vector. The output scan test vector is indeterminate in certain locations even for a correctly functioning device. The apparatus further comprises means for providing an output mask vector that identifies those locations in the output scan test vector that are indeterminate.

In accordance with yet another embodiment of the invention, there is provided test control apparatus. This apparatus comprises a communications interface that is operable for connection to a test device undergoing a scan test; a stored input scan vector for supply to the test device via the communications interface; and a stored mask vector for supply to the test device via the communications interface.

In accordance with yet another embodiment of the invention, there is provided a semiconductor device that includes support for scan testing. The device includes at least one port for receiving an input scan test vector and a mask vector and a scan sequence. The result of passing the input scan test vector through the scan sequence is an output scan test vector. The device further includes logic for combining the mask vector and the output scan vector to generate a masked output scan test vector.

It will be appreciated that such a device and apparatus can generally utilise the same particular features as described above in relation to the method embodiments.

### BRIEF DESCRIPTION OF THE DRAWINGS

Various embodiments of the invention will now be described in detail by way of example only with reference to the following drawings in which like reference numerals pertain to like elements and in which:

FIG. 1 is a schematic diagram illustrating a simplified generic stage in a semiconductor device;

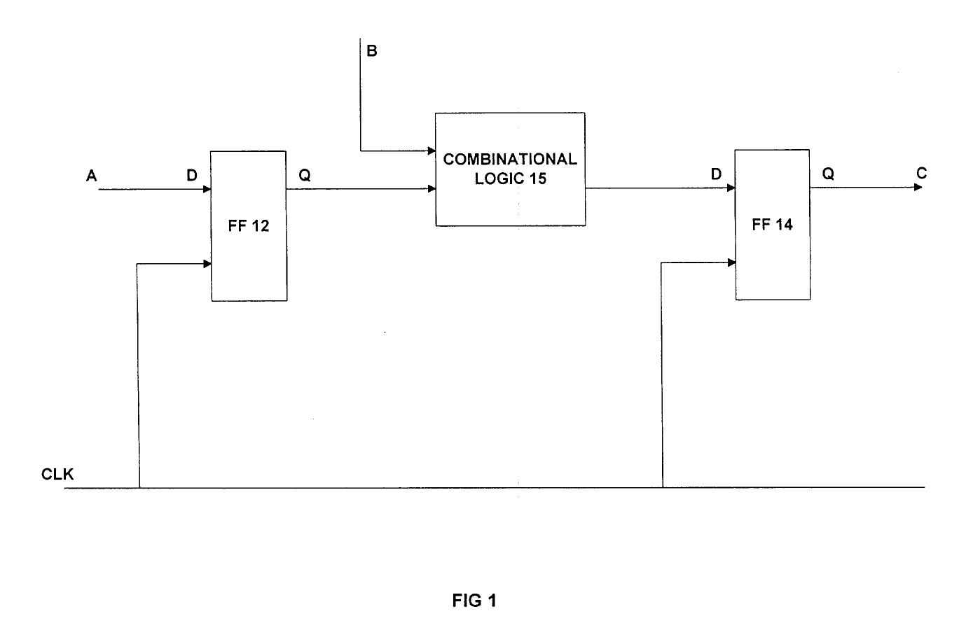

FIG. 2 illustrates the application of scan testing to the circuit of FIG. 1;

FIGS. 3A-3D illustrate the general operation of scan testing;

FIG. 4 is a schematic diagram of a semiconductor device in accordance with one embodiment of the invention;

FIG. 5 is a flowchart illustrating a method for performing scan testing in accordance with one embodiment of the invention;

FIGS. 6A and 6B are diagrams illustrating the use of a mask vector in accordance with the method of FIG. 5;

FIG. 7 is a generalised schematic diagram of a linear feedback shift register (LFSR) that can be used as a signature generator device in the embodiment of FIG. 5;

FIG. 8 is a schematic diagram of a semiconductor device in accordance with another embodiment of the invention; and

FIG. 9 is a schematic diagram of a semiconductor device and test apparatus in accordance with another embodiment of the invention.

### DETAILED DESCRIPTION

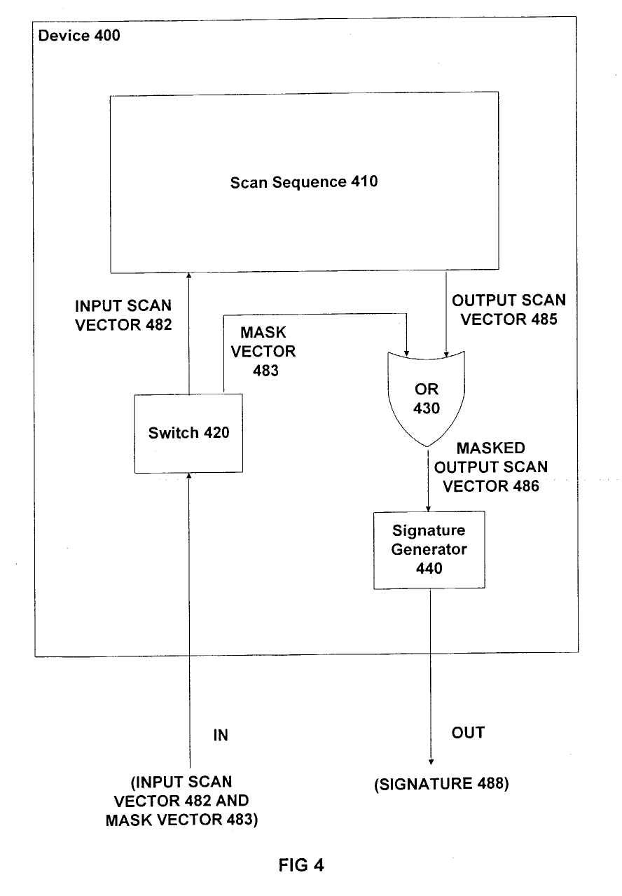

FIG. 4 illustrates a semiconductor device 400 in accordance with one embodiment of the invention. Note that device 400 can be used in any appropriate form of electronic equipment, for example, a computer, a consumer electronic device such as a television, and so on. Likewise, modern cars, aeroplanes, telecommunications apparatus, and many other systems incorporate complex electronics that could include device 400.

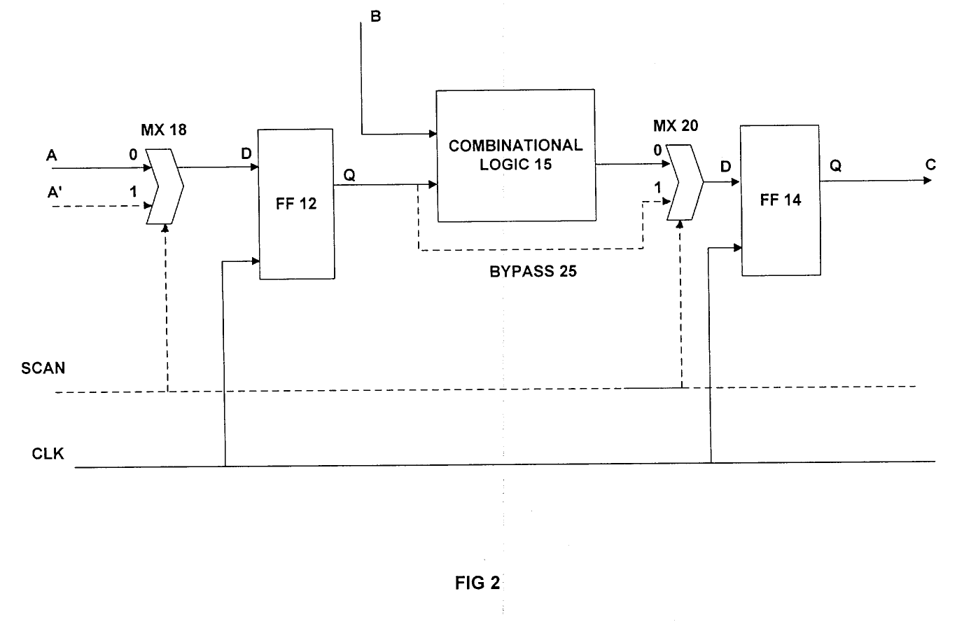

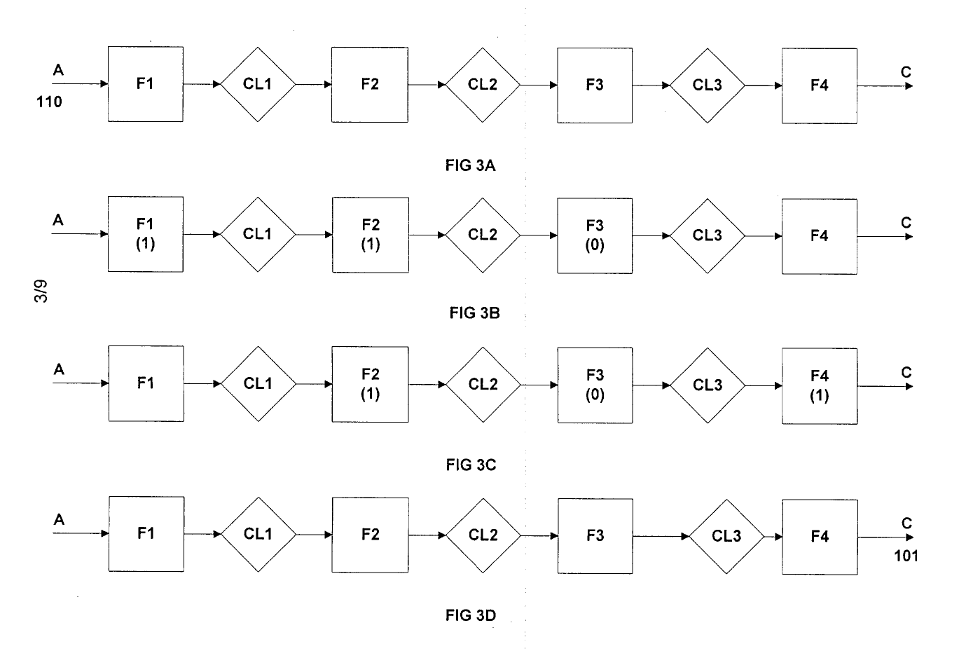

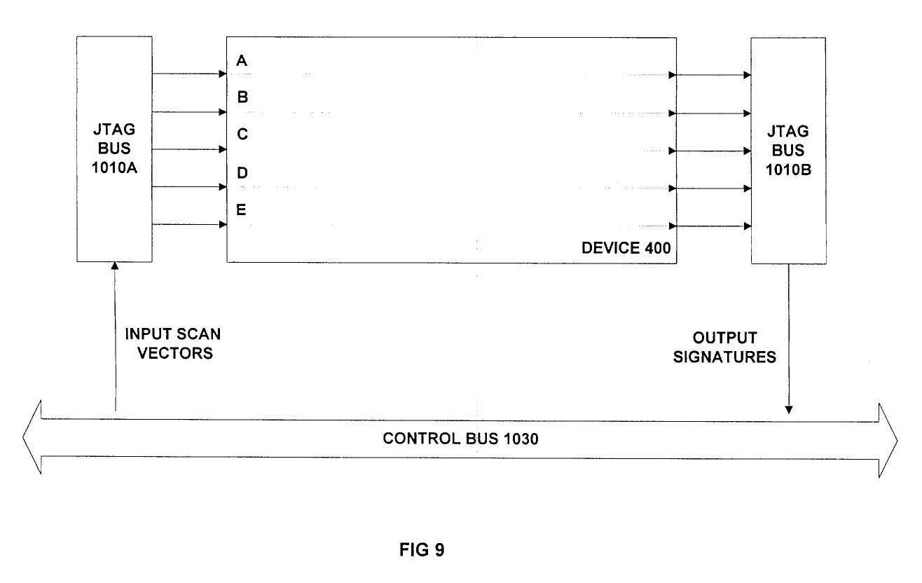

The device 400 includes a sequence 410 of flip-flops configured to support scan testing. In other words, scan sequence 410 comprises multiple stages such as shown in FIG. 2. In order to perform the scan test, the device 400 initially receives an input scan vector 482. One potential mechanism for feeding the input scan vector into the device is by using a JTAG bus, as will be discussed in more detail below, with reference to FIG. 9. The input scan vector 482 is passed to the scan sequence 410 via a switch 420, and then travels through the sequence in order to generate an output scan vector 485, as described above in relation to FIG. 3.

After the input scan vector has been loaded into the scan sequence 410, a mask vector 483 is input into device 400. The setting of the switch 420 is changed, so that rather than go to the scan sequence 410, the mask vector is instead routed to OR gate 430. There are a variety of possible mechanisms whereby the switch 420 can be appropriately controlled to achieve this. For example, in order to change the switch output from the scan sequence 410 to the OR gate 430 as required, the switch may be made responsive to some predetermined code at the end of the input scan vector, to an input scan vector of predetermined length, or to a delay between submitting the input scan vector and then the mask vector. A further possibility is that the setting of the switch is governed by a separate control line (not shown in FIG. 4).

One input of OR gate 430 therefore receives the mask vector 483 from switch 420. The other input of this OR gate 430 receives the output scan vector 485 from the scan sequence 410. The system is configured so that the mask vector arrives at the OR gate 430 at the same time as the output scan vector. This may be accomplished by appropriate relative timing for the supply of the input scan vector and the mask vector, and/or by the inclusion of some internal buffering (not shown in FIG. 4) inside device 400.

The OR gate 430 combines the mask vector and the output scan vector using the OR function on a bit-wise basis, with the output 486 from the OR gate 430 then being passed to a signature generator 440. This determines a signature 488 of the output from OR gate 430, as will be described in more detail below. This signature is then passed out from device 400 as representing the result of the scan test. (It will be appreciated that in some embodiments, OR gate 430 may be replicated a number of times, in order to allow blocks of the mask vector and the output scan vector to be combined in parallel).

Note that, if desired, the device 400 could include an authorisation unit (not shown in FIG. 4), such as described in the related application referenced above. This unit would calculate a digital signature of the input scan vector, which could then be compared either with a value already stored in the device 400, or with a value appended to the input scan vector itself, in order to ensure that the input scan vector has not been corrupted, or is not otherwise unsuitable for device 400. The authorisation unit then allows the scan test to proceed, providing this comparison achieves the expected match. However, if the signature does not match, the scan test is disabled, thereby protecting the device 400 against possible damage from an inappropriate scan vector.

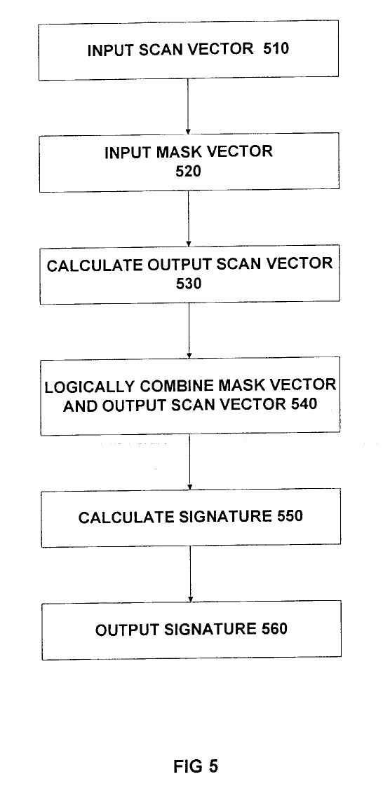

FIG. 5 is a flowchart that illustrates a method of performing a scan test in accordance with one embodiment of the present invention. The method commences with the input of the scan test vector (step 510), which is then followed by the input of the mask vector (step 520). The output scan vector is now calculated (step 530) by passing the input scan vector through the sequence of flip-flops to be tested. (Note that in a typical implementation, steps 520 and 530 are performed largely in parallel, in order to ensure that the output scan vector and the mask vector arrive simultaneously at the OR gate 430).

The output scan vector determined at step 530 is then logically combined with the mask vector (step 540). This logical operation ensures that the final output of the scan test is purely determinate. In particular, the masked vector is arranged so that those portions of the output scan vector that (a priori) are indeterminate are masked out (i.e. they are set to a pre-determined value), while those portions of the output scan vector that can be predicted for a properly operating device are not masked out.

The outcome 486 of the logical combination of the masked vector and the output scan vector is fed to a signature generator in order to calculate a signature of the masked output scan vector (step 550). The purpose of the signature is to represent the results of the scan test in a succinct and easily verifiable form. The signature is then output from the device as representative of the final outcome of the scan test.

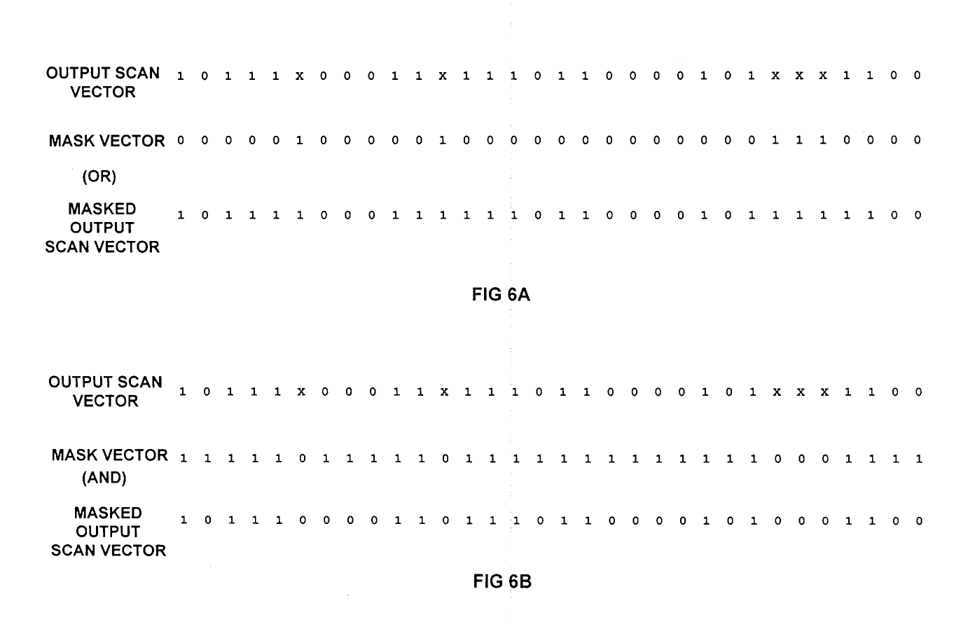

FIGS. 6A and 6B illustrate the use of the mask vector in order to provide a determinate output. Thus the top line in FIG. 6A represents the predicted output from a scan test for a device that is functioning correctly. In most locations it is known whether the output scan vector will be 0 or 1, but in certain positions the output cannot be predicted in advance. This is typically because these output values will depend on the state of some component which cannot or has not been initialised, and so is not known, or because they represent the output of a device that does not give a determinate output within the time period used for clocking a scan test. These indeterminate locations in the output scan vector are indicated in FIG. 6A by an X. (Note that although FIG. 6A illustrates a scan vector of 32 bits, in practice much longer sequences, such as 20 kbits, are typically used to test modern, complex semiconductor devices).

The second line in FIG. 6A represents a mask vector to be used in conjunction with the output scan vector of the first line. Thus the mask vector is set to 0 wherever the output scan vector has a known output (whether 1 or 0), and is set to 1 wherever the output scan vector is indeterminate. In other words, the mask vector contains a 1 in any position corresponding to an X in the output scan vector, and a 0 otherwise.

The final line of FIG. 6A represents the combination of the first two lines, namely the output scan vector and the mask vector, using a logical OR operation. It will be noted that this masked output scan vector is completely determinate in that there are no X values that have propagated into the masked output scan vector. This is due to the well-known behaviour of the OR-gate, which outputs a 1 as long as at least one of its inputs has a value of 1. Thus in this case, by making the mask 1 wherever the output scan vector is indeterminate, i.e., has a value X, it is ensured that the masked output scan vector has a value of 1, irrespective of the actual value of the output scan vector for any particular test.

(It will be appreciated that the output scan vector of FIG. 6A represents a theoretical prediction, rather than an actual output scan vector. Thus when a scan test is performed, the resulting output vector will not actually contain any Xs. Rather, any position indicated by an X in FIG. 6A will have a value of 0 or 1. However, it is not possible to determine in advance, based on a knowledge of the device and the relevant test, which one of these two outcomes will occur. Indeed, the result at these locations may vary from one run of the scan test to another. Hence the output at these positions is, a priori, indeterminate).

The advantage of using the mask vector is that the masked output scan vector comprises a set of values that can be completely predicted in advance (for a correctly functioning device). In the locations where the mask vector is set to 0, the values from the output scan vector are allowed to propagate into the masked output scan vector. This then allows these to be compared with the values expected for a correctly operating device, in order to obtain diagnostic information.

On the other hand, at those locations where the mask is set (i.e., equal to 1 in FIG. 6A), then the values of the masked output scan vector do not contain any useful information regarding the behaviour of the device under test, but are rather determined purely by the mask itself. However, this does not adversely impact the diagnostic process, since as previously explained, the motivation for masking out these values is that they cannot be reliably predicted for a correctly functioning device, and so do not contain useful diagnostic information anyway.

A slightly different embodiment of the invention is depicted in FIG. 6B. The first line of this Figure again represents an output scan vector. This output scan vector is, for purposes of illustration, the same as that of FIG. 6A, and so must be masked out at the same positions as for FIG. 6A. However, in the arrangement of FIG. 6B, the mask vector is defined, in effect, as the opposite or negative of the mask vector of FIG. 6A. Thus the positions that must be masked out are represented in FIG. 6B by a 0, while those locations that are determinate and do not need to be masked out are represented by a 1. (This is the reverse of the arrangement of FIG. 6A, where a 1 indicates a masked position, and a 0 indicates a non-masked position).

The logical operation used to combine the output scan vector with the mask vector of FIG. 6B is an AND-gate. Thus in this embodiment, the OR gate 430 of FIG. 4 (and as used for the logical combination of FIG. 6A) is replaced by an AND-gate. This operation then leads to the masked output scan vector shown in the bottom line of FIG. 6B. As with FIG. 6A, it will be appreciated that this masked output scan vector is completely determinate, in that all the Xs from the output scan vector have been eliminated. More particularly, these indeterminate locations have been replaced in the masked output scan vector by a 0 (in contrast to the arrangement of FIG. 6A, where the indeterminate values are replaced by a 1).

It will be appreciated therefore that the overall outcome of FIG. 6B is basically the same as that of FIG. 6A. Thus it is of little significance whether the masked values are represented by a 0 or a 1 in the output scan vector (as long as this is done consistently), since as previously explained, these positions in the output vector do not contain any useful diagnostic information. Accordingly, the approach of either FIG. 6A or 6B may be adopted, depending on the particular circumstances of the semiconductor device to be tested (for example whether it is easier to fabricate an OR-gate or an AND-gate on the device).

Returning to FIG. 4, the purpose of the signature generator 440 is to calculate a function of the output scan vector that is much more concise than the output scan vector itself, but still highly sensitive to any slight change in the output scan vector. This then allows the proper operation of the device 400 to be confirmed by checking that the output signature has the expected value. Even a minor discrepancy in the output scan vector from that predicted for correct operation of the device will alter the value of the calculated signature, and hence be readily detectable. Of course, if a variety of input scan vectors are used for testing a particular device, each having its own predicted (and masked) output scan vector, then generally a different signature will be expected for each such different input scan vector. (For more information about the use of signature analysis in the testing of semiconductor circuits, see the above-referenced book on “Fault Diagnosis of Digital Circuits” by V Yarmolik).

Suitable mathematical functions for use in the signature generator 440 are already widely available, for example from cryptography-based digital signature techniques. Such applications usually adopt a two-stage process, in which the first step is to calculate a hash or digest of an input message. One standard technique for calculating a digest is known as the Secure Hashing Algorithm (SHA). This is widely used in cryptography-based digital signature techniques, and is described in detail at: http://www.itl.nist.gov/fipspubs/fip180-1.htm. The SHA produces a 160-bit output representing a message digest from an input message of any length of up to 2⁶⁴ bits. For the second step, this hash or digest is then encrypted using a private key of the message originator to provide an authenticating digital signature (see http://www.abanet.org/scitech/ec/isc/dsg-tutorial.html for a general discussion of digital signature techniques).

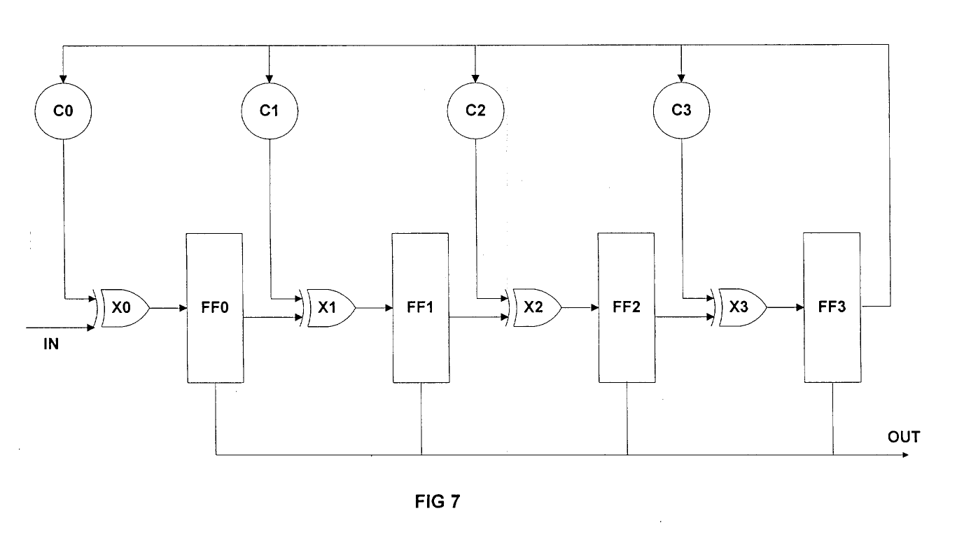

Note that the signature generator 440 of device 400 only needs to perform the first of these two steps, to calculate a hash or digest, rather than having to calculate a full cryptographic digital signature. Of course, signature generator 440 may optionally encrypt its hash or digest, but there seems little benefit in such additional processing and complexity. (There is generally no need to encrypt the hash or digest of the output scan vector, since the contents of this vector, in themselves, are not normally of value). Thus in one embodiment of FIG. 4, signature generator 440 calculates the SHA for an input scan vector. However, it will be appreciated that the SHA represents just one of many available techniques that can potentially be adopted for signature generator 440. Another possibility is based on the use of a linear feedback shift register (LFSR), which is shown in generalised form in FIG. 7. Such an LFSR can be used as the basis of a very simple and effective implementation of signature generator 440.

As shown in FIG. 7, each stage of the LFSR comprises a two-input XOR gate and a flip-flop (X0, FF0; X1, FF1; X2, FF2; and X3, FF3). An input to the LFSR is provided to one input of the XOR gate of the first stage (X0 in FIG. 7). The output from the LFSR is then taken in parallel from the flip-flops of the various stages, as shown in FIG. 7.

For each stage, one input of the XOR gate is connected to the output of the flip-flop of the preceding stage. The other input of the XOR is potentially connected by a feedback loop to the output of the LFSR, dependent upon whether a corresponding connection (C0, C1, C2, and C3) is open or closed. (Note that if a connection is open, then the corresponding XOR gate can clearly be omitted as redundant). Any given LSFR can be represented by a polynomial, which specifies which particular connections are open or closed. For example, in FIG. 7, the polynomial X³+X¹+1 would imply that C2 is open, and the remaining connections (C0, C1, and C3) are closed.

All the stages of the LSFR are clocked at the same time (for simplicity the clock signal is omitted from FIG. 7). This causes the state of the LFSR, as determined by the contents of the flip-flops (FF0-FF3), to transition from one state to another, dependent upon the particular polynomial and the starting state of the LFSR. Certain polynomials are known to produce maximal length LFSRs, whereby, in the absence of input, an m-bit LSFR will cycle through 2^{m}−1 different states before repeating itself (the one state omitted from the sequence is all zeros). Such LFSRs are frequently used for generating pseudo-random bit sequences, and are described for example at pages 655-657 in: “The Art of Electronics” by Horowitz and Hill, 1989, Cambridge University Press (ISBN 0-521-37095-7).

Note that although the LFSR of FIG. 7 comprises four stages, which would lead to a 4-bit signature value, the implementation of signature generator 440 will generally produce a rather longer signature value (for example, by having more stages in the LFSR). Thus if the signature value is m-bits in length, then for a good hashing function, the probability that an arbitrary scan vector will have a given signature value is 1/(2^{m}−1). This then corresponds to the chance probability of a false-positive; i.e., the probability that the output signature inadvertently happens to match the expected value, even though the (masked) output scan vector itself contained one or more errors. It will be appreciated therefore, that by increasing the length, m, of the signature value, this probability can be reduced to an acceptably small value, albeit at the possible expense of somewhat increased complexity or cost. For example, a typical output signature might perhaps have a length in the range from 64 to 512 bits for present day technology, depending on the device concerned, although other values could also be used, according to the particular circumstances.

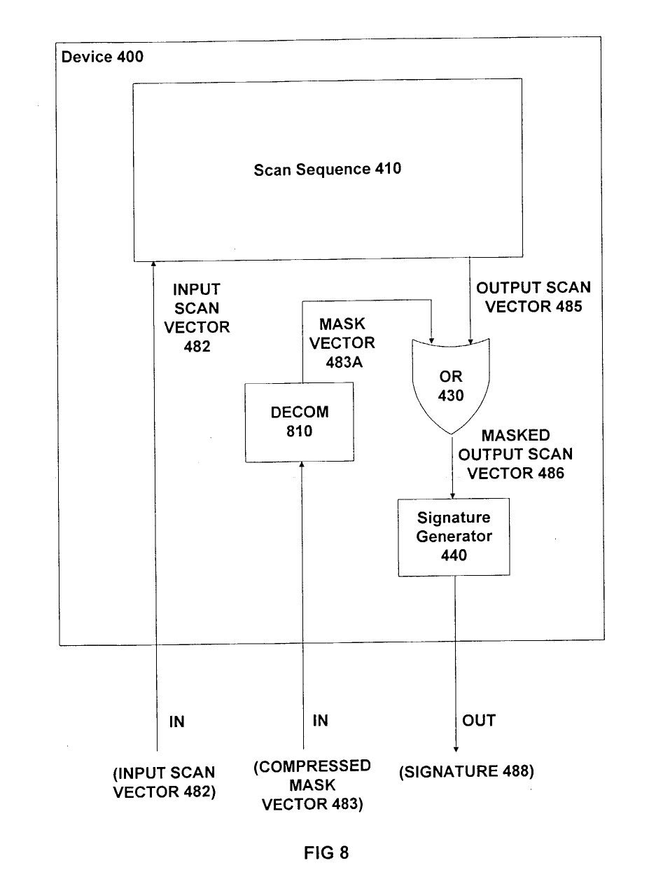

FIG. 8 represents an alternative implementation of a semiconductor device 400 in accordance with one embodiment of the invention. Many of the components in this diagram are the same as for the embodiment of FIG. 4 (and so will not be discussed again), but the input configuration of FIG. 8 is different. Thus this time separate input paths are provided for the input scan vector 482 and for the mask vector 483, rather than these being sequentially input on the same line.

Also shown in FIG. 8 is a decompression unit 810. Thus the mask vector 483 initially supplied to device 400 is in compressed format, and accordingly has to be routed through decompression unit 810 prior to becoming available for use as a mask. Note that since a mask vector typically contains a large number of 0s, it can normally be compressed with a high degree of efficiency. For example, the well known run length encoding (RLE) technique may be used as an appropriate compression algorithm.

The decompression unit 810 in device 400 therefore receives the incoming masked vector 483 in compressed format, and then decompresses it to generate the operational mask vector 483A (such as shown in the middle line of FIGS. 6A and 6B). This is then passed to the OR gate 430, where it is utilised in the same manner as described above in relation to FIG. 4.

It will be appreciated that the output scan vector 485 and the (decompressed) mask vector 483A need to arrive in synchronism at the OR gate 430 in order for the masking operation to proceed correctly. Therefore, the mask vector 483A cannot be directly utilised until the output scan vector 485 is produced. In turn, the output scan vector does not begin to become available until the input scan vector 482 has been completely read in, as shown in FIG. 3.

In general, the path length through the scan sequence 410 is much greater than through decompression unit 810. The simultaneous provision to the device 400 of both the input scan vector 482 and the (compressed) mask vector 483 therefore requires a buffer (not shown in FIG. 8) for the mask vector somewhere on the device, in order to delay its arrival at OR gate 430. (Note that if the buffer is located on the input side of the decompression unit, then a smaller amount of space will be required for the mask vector than if the buffer were located on the output side, since it permits the mask vector to be stored in compressed format). However, it is generally more convenient for the external test system to delay the input of the mask vector in compressed format to the device 400 until the input scan vector has been largely (if not completely) read into the device. This then eliminates (or at least reduces) the need to provide buffering on the device itself. The skilled person will be aware of various techniques that may be used to ensure proper synchronisation of the output scan vector 485 and the mask vector 483A.

Note that a decompression unit 810 such as shown in the embodiment of FIG. 8 could also be included, if desired, in the embodiment of FIG. 4. In this case, the decompression unit would typically be positioned between switch 420 and OR-gate 430. Alternatively, it could be positioned on the input side of switch 420, but in this case there would need to be some control facility to prevent it trying to decompress the input scan vector itself (unless of course the input scan vector was also compressed in the same way as the mask vector). One way of achieving this would be to provide a control line to both the switch and the compression unit. This would then indicate when the mask vector was being input, thereby allowing the switch and compression unit to be set accordingly. A further possibility is that the decompression of the mask vector may be performed off-chip, before being loaded into device 400, by some external test device, rather than by providing a decompression unit on the device itself.

FIG. 9 illustrates another embodiment of the invention, in which a device 400 is subjected to multiple scan tests in parallel. This is accomplished by providing a JTAG bus 1010, including an input section 1010A and an output section 1010B. (JTAG is a well-known standard for board testing, known formally as the IEEE 1149.1 Standard Test Access Port and Boundary Scan, and is described, for example, in the white paper “Introduction to JTAG Boundary Scan” available at http ://www.sun.com/microelectronics/whitepapers/wpr-0018-01). The JTAG bus sections 1010A and 1010B are both connected to a control bus 1030. This may simply represent a continuation of the JTAG bus 1010, or it may represent some other bus.

The device 400 incorporates five independent scan sequences (each corresponding to a single scan sequence 410, such as shown in FIG. 4), although it will be appreciated of course that the number of such scan sequences may vary from one embodiment to another. In FIG. 9, the five different scan sequences are labelled A, B, C, D, and E. The use of such multiple chains in parallel reduces the time needed for a given scan test to be performed (compared to having one very long scan sequence), and also can make it easier to avoid overly long connections between components of the same scan sequence. Note that a separate mask vector as described above is typically utilised for each scan sequence in FIG. 9 (although for reasons of space, the relevant details are omitted from FIG. 9 itself).

There is a serial data input onto JTAG bus 1010A. Thus the five input scan vectors, corresponding to scan sequences A, B, C, D, and E, are all multiplexed in a single path onto the JTAG bus 1010A. A serial to parallel conversion is then performed, as the separate input scan vectors are demultiplexed, and fed to their corresponding scan sequence.

After the scan tests have been performed (in parallel) for sequences A, B, C, D, and E, each of the resultant output scan vectors is combined with a corresponding mask vector. The set of mask vectors is provided over JTAG bus 1010, potentially in compressed form (in which case the vectors need to be decompressed before combination with the output scan vectors). The result of this combining operation is a set of masked output scan vectors. A signature is now calculated for each of the masked output scan vectors, and a parallel to serial conversion is performed on the five output digital signatures. Thus these are multiplexed together to form a single overall output result, which is fed out from the JTAG bus 1010B for further analysis.

Test control apparatus (not shown in FIG. 9) is typically attached to control bus 1030 in order to drive the scan test. Such test control apparatus may be included on the same board as device 400, or may be provided in a separate board or system (in which case it would generally be connected to control bus 1030 by some suitable form of data connection or network link). Note that the test control apparatus may comprise standalone equipment, such as a portable test unit, or may represent a diagnostic facility incorporated into a broader, functional, system.

In the above embodiments, the masked output scan vector has been made determinate by using the mask vector to set any (a priori) indeterminate values to a fixed value. However, in an alternative embodiment, the output mask vector 483 may be used to excise indeterminate values from the output scan vector. In other words, rather than performing an OR operation between the mask vector and the output scan vector, a different logic operation is employed. Thus the mask vector could be formed so that a first value (e.g. 0) indicates that the corresponding bit in the output scan vector should go into the signature generator 440, while a different value (e.g. 1) indicates that the corresponding bit in the output scan vector does not go into the signature generator. It will be appreciated that the masked output scan vector is now determinate (and also shorter), since the indeterminate bits have been removed. This approach may be adopted if constraining the size of the output scan vector is important, although the implementation is typically more complex than the simple use of an OR gate, such as shown in the embodiment of FIG. 4.

Furthermore, the embodiments described above have all converted the (masked) output scan vector 486 into a signature 488 for subsequent checking. Nevertheless, it will be appreciated that such conversion is optional. Thus in other embodiments, the masked output scan vector, with the indeterminate bits excised or set to a fixed value, may be passed off the device and/or analysed directly (such as has conventionally occurred with known systems like those shown in FIGS. 2 and 3).

However, the use of a mask vector does facilitate the generation of a signature, if desired, since it ensures that the output scan vector is completely determinate. This in turn leads to a readily predictable signature (for a correctly functioning device). The advantage of characterising the output scan vector by its signature is that the signature is highly compact compared to the full output scan vector, and so can be easily transmitted to and then manipulated and/or stored by other devices within the system. This then provides considerable flexibility in the area of diagnostics and system management.

For example, in a complex system there may be a system or control facility that directs various components within the system to perform a scan test, either at system start-up, and/or following the report of an error. The components then report the signatures resulting from these scan tests back to the control facility. This approach requires far less system bandwidth than transmitting the corresponding full output scan vectors to the control facility. In addition, it provides a compact and succinct representation of the results for the control facility to examine in order to confirm that the corresponding components are working properly.

Note that rather than report the signature from the scan test back to the control facility, a component could itself compare the signature to an expected value. The component then alerts the control facility in the event of a mismatch between the expected signature and the observed signature from the output scan vector. This can be done by sending an interrupt or similar signal to the control facility. One advantage of this approach is that most existing systems already include support for interrupt signalling in their infrastructure.

The input scan vector, mask vector, and expected signature result can be stored within the component being tested, for example within a special purpose ROM. Alternatively, they may be supplied from some external source, such as the control facility itself, or some other appropriate storage subsystem (for example, a disk storage unit). Note that in the latter case, the control facility may direct the component to retrieve the input scan vector and mask vector from the storage subsystem. The expected signature result can then be retrieved by the component in conjunction with the input scan vector and mask vector, or provided directly to the component by the control facility itself.

Note also that the digital signature may be calculated from multiple output mask vectors. Thus for example, a set of two or more input scan vectors may be used to test different portions of a device and/or different operations within the same portion of a device, resulting in the production of multiple output scan vectors. A single signature may then be generated which is representative of all these output scan vectors.

In conclusion, a variety of particular embodiments have been described in detail herein, but it will be appreciated that this is by way of exemplification only. The skilled person will be aware of many further potential modifications and adaptations that fall within the scope of the claimed invention and its equivalents.

1. A method for scan testing a semiconductor device comprising the steps of:
providing an input scan test vector;
processing the input scan test vector through the device to produce an output scan test vector comprising a sequence of locations each having a value, wherein one or more locations in said sequence are, a priori, indeterminate in value, even if said device is functioning correctly;
providing an output mask vector, wherein said mask vector identifies those one or more locations in the output scan test vector that are, a priori, indeterminate in value; and
combining the output scan test vector with said output mask vector using a logical operation to produce a determinate masked output scan test vector.

2. The method of claim 1, further comprising the step of producing a signature from at least a portion of the masked output scan test vector.

3. The method of claim 2, wherein the signature is produced using a hashing function.

4. The method of claim 2, wherein the signature is produced using a linear feedback shift register.

5. The method of claim 2, further comprising the step of comparing said signature with a predetermined value to determine whether or not the device is functioning correctly.

6. The method of claim 5, wherein said step of comparing is performed within said semiconductor device.

7. The method of claim 6, further comprising the step of sending an interrupt if the signature does not match said predetermined value.

8. The method of claim 1, wherein the output mask vector is provided in compressed form, and the method further comprises the step of decompressing the output mask vector prior to combining with the output scan test vector.

9. The method of claim 8, wherein the output mask vector is compressed using run length encoding.

10. The method of claim 1, wherein the output mask vector comprises a sequence of locations, each having a binary value and corresponding to a different one of the locations in the output scan test vector, and wherein a location in the output mask vector has a binary value of 1 if the corresponding location in the output scan test vector is, a priori, indeterminate, and a binary value of 0 otherwise.

11. The method of claim 10, wherein said logical operation comprises an OR function.

12. The method of claim 1, wherein the output mask vector comprises a sequence of locations, each having a binary value and corresponding to a different one of the locations in the output scan test vector, and wherein a location in the output mask vector has a binary value of 0 if the corresponding location in the output scan test vector is, a priori, indeterminate, and a binary value of 1 otherwise.

13. The method of claim 12, wherein said logical operation comprises an AND function.

14. The method of claim 1, wherein the masked output scan test vector comprises a sequence of locations, each corresponding to a different one of the locations in the output scan test vector, and wherein all those locations in the masked output scan test vector that correspond to a location in the output scan test vector that is, a priori, indeterminate have the same value in the masked output scan test vector.

15. The method of claim 1, further comprising the step of comparing the masked output scan test vector against a predetermined vector in order to ascertain whether or not the device is functioning correctly.

16. The method of claim 1, wherein the masked output scan test vector is produced from the output scan test vector by excising those locations in the output scan test vector that are, a priori, indeterminate in value.

17. A method for scan testing a device, comprising the steps of:
processing an input scan test vector through the device to produce an output scan test vector;
combining the output scan test vector with an output mask vector in order to produce a determinate masked output scan test vector.

18. Apparatus for scan testing a device comprising:
means for providing an input scan test vector, wherein the input scan test vector is to be processed through the device in order to produce an output scan test vector comprising a sequence of locations each having a value, wherein one or more locations in said sequence are, a priori, indeterminate in value, even if said device is functioning correctly; and
means for providing an output mask vector, wherein said mask vector identifies those locations in the output scan test vector that are indeterminate.

19. Test control apparatus comprising:
a communications interface that is operable for connection to a test device undergoing a scan test;
a stored input scan vector for supply to the test device via said communications interface; and
a stored mask vector for supply to the test device via said communications interface.

20. The test control apparatus of claim 19, wherein a signature representing the outcome of a scan test is receivable back from the test device via said communications interface.

21. The test control apparatus of claim 19, wherein an interrupt signal is receivable back from the test device via said communications interface if a signature representing the outcome of a scan test does not match a predetermined value.

22. The test control apparatus of claim 21, wherein said predetermined value is supplied to the test device via said communications interface.

23. A semiconductor device including support for scan testing, said device including:
at least one port for receiving an input scan test vector and a mask vector;
a scan sequence, wherein the result of passing the input scan test vector through the scan sequence is an output scan test vector; and
logic for combining the mask vector and the output scan test vector to generate a masked output scan test vector.

24. The device of claim 23, wherein the output scan test vector comprises a sequence of locations each having a value, wherein one or more locations in said sequence are, a priori, indeterminate in value, even if said device is functioning correctly, and wherein the mask vector identifies the one or more locations in the output scan test vector that are, a priori, indeterminate in value.

25. The device of claim 24, further comprising a signature generator for operating upon the masked output scan test vector.

26. The device of claim 25, wherein the signature generator determines a hashing function of the masked output scan test vector.

27. The device of claim 25, wherein the signature generator comprises a linear feedback shift register.

28. The device of claim 25, further comprising a comparator for confirming that a signature produced by the signature generator matches an expected value for the signature.

29. The device of claim 28, wherein the device signals an interrupt, if the comparator does not detect a match.

30. The device of claim 23, further comprising a decompression unit attached to said at least one port, wherein the mask vector is received by the device in compressed format.

31. The device of claim 24, wherein the output mask vector comprises a sequence of locations, each having a binary value and corresponding to a different one of the locations in the output scan test vector, and wherein a location in the output mask vector has a binary value of 1 if the corresponding location in the output scan test vector is, a priori, indeterminate, and a binary value of 0 otherwise.

32. The device of claim 31, wherein said logic comprises an OR gate.

33. The device of claim 24, wherein the output mask vector comprises a sequence of locations, each having a binary value and corresponding to a different one of the locations in the output scan test vector, and wherein a location in the output mask vector has a binary value of 0 if the corresponding location in the output scan test vector is, a priori, indeterminate, and a binary value of 1 otherwise.

34. The device of claim 33, wherein said logic comprises an AND gate.

35. The device of claim 24, wherein said logic generates the masked output scan test vector from the output scan test vector and the output mask vector by excising those locations in the output scan test vector that are, a priori, indeterminate in value.

36. Apparatus supporting a scan test facility, said apparatus comprising:
means for receiving an input scan test vector;
means for processing the input scan test vector to produce an output scan test vector comprising a sequence of locations each having a value, wherein one or more locations in said sequence are, a priori, indeterminate in value, even if the device is functioning correctly;
means for receiving an output mask vector, said mask vector identifying the one or more locations in the output scan test vector that are, a priori, indeterminate in value; and
means for combining the output scan test vector with said output mask vector using a logical operation in order to produce a determinate masked output scan test vector.

37. Apparatus comprising:
a control facility;
a component to undergo a scan test; and
a communications link between the control facility and said component;
wherein said component includes:
a scan sequence for generating an output scan vector from an input scan vector as a result of a scan test; and
logic for combining the output scan vector with a mask vector to generate a masked output scan test vector.

38. The apparatus of claim 37, wherein a scan test is performed in the component in response to a command from the control facility.

39. The apparatus of claim 37, wherein the component further includes a signature generator for calculating a signature from the masked output scan test vector.

40. The apparatus of claim 39, wherein the component sends an interrupt to the control facility, if the calculated signature does not match an expected value.
